(19) United States
(12) Patent Application Publication
(10) Pub. No.: US 2010/0258909 A1
(43) Pub. Date: Oct. 14, 2010

(54) Longitudinal link trimming and method for increased link resistance and reliability

(75) Inventors: Eric L. Hoyt, Tucson, AZ (US); Eric W. Beach, Tucson, AZ (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 12/386,118

(22) Filed: Apr. 14, 2009

(51) Int. Cl. H01L 27/10; H01L 21/02; H01C 1/012

(52) U.S. Cl. 257/536; 438/385; 338/306; 257/E27.071; 257/E21.004

(57) ABSTRACT

A resistor (14) and a resistive link (1,15) are provided in an integrated circuit structure, and a dielectric layer (30-2) is formed over the resistive link. The resistor and the resistive link are connected in parallel. The resistance of the resistor is trimmed by forming a cut entirely through the resistive link, by advancing a laser beam (3) through a trim region (4,4-1) of the resistive link in a direction at an angle in the range of approximately 0 to 60 degrees relative to a longitudinal axis of the resistive link so as to melt resistive link material. The advancing laser beam tends to sweep the melted material in the direction of beam movement. Re-solidified link debris accumulates sufficiently far apart and sufficiently far from a stub (15A) of the resistive link to prevent significant leakage current in the resistive link.

### BACKGROUND OF THE INVENTION

The present invention relates generally to methods for laser trimming of resistive links, such as resistive links composed of sichrome (SiCr), nichrome (NiCr), polycrystalline silicon, and numerous other resistive materials that may be used to form trimmable resistive links in integrated circuits to increase the reliability of the trimmed links.

Trimmable resistors are commonly used in the semiconductor industry. For example, a typical trimmable resistor may include a number of elongated, SiCr resistive links connected in parallel with a fixed-value resistor. The resistances of such trimmable resistors have been trimmed, i.e., adjusted by guiding a focused laser beam laterally (i.e., perpendicular to the longitudinal axis of the SiCr resistive link) across one or more of the parallel-connected SiCr resistive links. (The difference between a trimmable “resistive link” and a trimmable thin film “resistor” is that a resistive link is a laser cut is made all the way through a resistive link so as to form an open circuit, while a trimmable resistor always has a significant resistance and conducts a significant current in response to an applied voltage.

The prior art includes the article “Laser Interaction with SiCr Thin-Film Resistors ‘The Bubble Theory’” by Edward Coyne, 41st Annual IEEE International Reliability Physics Symposium Proceedings, pp. 553-558, Mar. 30 through Apr. 4, 2003 (URL: http://ieeexplore.ieee.org/stamp/stamp.jsp?arnumber=1197807&isnumber=26927). This article presents a theoretical analysis of the mechanisms involved during laser trimming of SiCr thin-film resistors, and also discloses lateral movement of the laser beam, perpendicular to the intended direction of current flow through the SiCr thin film resistor as shown in FIG. 1 therein. It is believed that such lateral advancing of the laser beam is representative of the closest prior art.

Referring to “Prior Art” FIGS. 1A-1D herein, a laser beam is moved from left to right across SiCr link 1 as indicated by arrows 7A so that the laser beam spot 3 on the surface of an integrated circuit chip moves laterally across a midpoint of SiCr resistive link 1. In the plan view of FIGS. 1A-1D, four stages are shown to indicate the progression of the lateral movement of laser beam spot 3 across SiCr link 1 in order to cut it.

As subsequently described with reference to FIGS. 3 and 4, it has been found that as laser beam 3 moves laterally across trim region 4 of SiCr link 1, SiCr material of link 1 in the vicinity of laser beam 3 is melted and “pushed” outward to the upper boundary of the SiO2 layer that exists around, above, and below each SiCr link 1 as laser beam 3 advances, because there is nowhere else for melted chromium produced by the melting of the SiCr material to flow. (It is believed that after the melting, the silicon and chromium become separated.) Consequently, the melted chromium is blocked by the bounding SiO₂, and tends to reflow back into the “opened-up” trim region 4 which at that point has been laser-cut and is now also bounded by “stubs” 1A and 1B of SiCr link 1. The melted chromium material which flows back into the opened-up trim region 4 then re-solidifies, after laser beam 3 has been turned off or moves beyond trim region 4. Re-solidified chromium material also can form a conductive “residual filament” 5, as shown in FIG. 1D.

It has been suggested that such a residual filament 5 formed on the trailing edge of a lateral laser beam cutting through a SiCr link can be removed by another lateral laser cut, in the opposite direction. This technique is shown in FIGS. 2A-2D, wherein a second pass of laser beam 3 begins from the right of previously cut SiCr link 1, as indicated by arrows 7B. Laser beam 3 then moves further to the left through trim region 4, attempting to widen the cut through trim region 4 both by melting and removing more of lower SiCr stub 1A and by re-melting some of residual filament 5, as indicated in FIG. 2B. When laser beam 3 has moved beyond trim region 4 in the direction of arrow 7B, as indicated in FIG. 2A, the remaining residual filaments 5A and 5B are relatively small. It is believed that although the prior art shows causing laser beam 3 to retrace the path shown in Prior Art FIGS. 1A-1D, the prior art does not disclose providing a downward offset of laser beam 3 as indicated by arrow 9 in FIGS. 2A-2D. (However, the present inventor has found that offsetting the right-to-left laser beam 3 downward by a distance of 1 micron (μ) relative to the left-to-right path shown in Prior Art FIGS. 1A-1D provides an improvement but nevertheless results in an unacceptably high level of link failures in reliability testing.)

As subsequently explained with reference to FIGS. 3 and 4, the reliability of the lateral laser cuts of SiCr links described above has been problematic, because sometimes chromium debris resulting from the laser cutting of a SiCr link remains in the “trim region” cut by laser beam 3 between the inner ends of SiCr “stubs” 1A and 1B of the laser-cut link. The remaining chromium debris may cause unacceptable leakage current through the trimmed SiCr link, causing it to fail testing to determine whether or not the SiCr link has been completely and adequately cut. The chromium debris remaining after the prior art lateral laser cutting of SiCr links reduces the manufacturing yield of integrated circuits including such laser-trimmed SiCr links.

There is an unmet need for an improved method of increasing the reliability of laser-trimmed resistive links composed of material such as such as SiCr, NiCr, polycrystalline silicon, or other thin-film material, especially laser-trimmed resistive links as used in integrated circuits.

There also is an unmet need for an improved method of laser trimming a resistive link, such as a SiCr, NiCr, polycrystalline silicon, or other resistive link, to reliably eliminate leakage current paths through the trimmed region of the resistive link.

There also is an unmet need for improved reliability of laser trimmed resistive links in integrated circuits by eliminating voltage-dependant leakage currents through the laser-trimmed resistive links.

### SUMMARY OF THE INVENTION

It is an object of the invention to provide an improved method of increasing the reliability of laser-trimmed resistive links, such as SiCr, NiCr or other thin-film resistive links, especially as used in integrated circuits.

It is another object of the invention to provide an improved method of laser trimming a resistive link, such as a SiCr, NiCr, polycrystalline silicon, or other resistive link, to reliably eliminate leakage current paths through the trimmed region of the resistive link.

It is another object of the invention to provide improved reliability of laser trimmed resistive links in integrated circuits by eliminating voltage-dependant leakage currents through the laser-trimmed resistive links.

It is another object of the invention to provide improved reliability of laser trimmed SiCr resistive links by eliminating voltage-dependant leakage currents through the laser-cut region of resistive link.

It is another object of the invention to provide a method of improving the reliability of a laser-trimmed SiCr resistive link by more effectively clearing chromium debris produced by the laser trimming out of a trim area of the resistive link.

It is another object of the invention to provide an improved method of laser trimming a resistive link which reliably eliminates leakage current paths through the trimmed region of the SiCr link by providing longitudinal or diagonal laser cuts through the resistive link.

Briefly described, and in accordance with one embodiment, the present invention provides a circuit element (14) and a resistive link (1,15) in an integrated circuit structure, and a dielectric layer (30-2) is formed over the resistive link. The circuit element is connected to the resistive link. A cut is made entirely through the resistive link by advancing a laser beam (3) all the way through a trim region (4,4-1) of the resistive link in a direction at an angle in the range of approximately 0 to 60 degrees relative to a longitudinal axis of the resistive link so as to melt resistive link material. The advancing laser beam sweeps melted material in the direction of beam movement. Re-solidified link debris accumulates in the trim region sufficiently far apart and sufficiently far from a stub (15A) of the resistive link to prevent significant leakage current in the resistive link.

In one embodiment, the invention provides a method of adjusting a resistance of a resistive structure (15B) including a first resistor (14) and a first resistive link (15), the method including providing the first resistor (14) and the first resistive link (1,15) in an integrated circuit structure being fabricated, forming a dielectric layer (30-2) over the first resistive link (1,15), connecting the first resistor (14) and the first resistive link (1,15) in parallel, and forming a cut entirely through the first resistive link (1,15) by advancing a laser beam (3) through a trim region (4,4-1) of the first resistive link (1,15) in a direction that is at an angle in the range of approximately 0 to 60 degrees with respect to a longitudinal axis of the first resistive link (1,15) so as to melt material of the first resistive link (1,15) in the trim region (4,4-1).

In one embodiment, a plurality of resistive links (15-18) are formed in the integrated circuit. The dielectric layer (30-2) is formed over the plurality of resistive links (15-18). The first resistor (14) and the plurality of resistive links (15-18) are connected in parallel. Cuts are formed in entirely through each of the plurality of resistive links (15-18), respectively, by advancing the laser beam (3) through trim regions (4-1,2,3,4) of the plurality of resistive links (15-18) in directions that are at angles in the range of 0 to 45 degrees with respect to longitudinal axes of the plurality of resistive links (15-18), respectively, so as to melt resistive material of the plurality of resistive links (15-18) in the trim regions (4-1,2,3,4) thereof. In one described embodiment, the angle is 25 degrees, and in another described embodiment the angle is zero degrees. In a described embodiment, material of the first resistive link (1) is melted by advancing the laser beam (3) in the vicinity of the cut and thereby sweeping melted material in the direction in which the laser beam (3) is advancing. The sweeping results in re-solidified debris pieces (20A) remaining in the vicinity of the cut and being located sufficiently far from an edge (15A) of the cut to prevent leakage current from flowing through the first resistive link (1,15) after it has been laser-cut. In a described embodiment, the plurality of SiCr links (15-18) includes four resistive links. The resistive links (1,15) can be composed of a material from the group consisting of NiCr, NiCr alloy, SiCr alloy, NiCr silicide, SiCr silicide, TiN, TiN alloy, TaN, Ta alloy, polycrystalline silicon, or cermet material. In one embodiment, the first resistor (14) and the first resistive link (1,15) are composed of the same kind of material.

In one embodiment, after a first longitudinal cut has been made by advancing the laser beam (3) through the trim region (4,4-1), a second longitudinal cut is made by advancing the laser beam through the trim region in a second direction opposite to the first direction of the first cut. In another embodiment, after a first diagonal cut has been made by advancing the laser beam through the trim region in a first diagonal direction, then the laser beam (3A) is advanced back through the first diagonal cut in another direction so as to round off edges of first (15A) and second (15B) stubs of the first resistive link (15).

In one embodiment, the invention provides an integrated circuit structure (15B) including a circuit element (14) and a resistive link (1,15). A dielectric layer (30-2) is disposed on the resistive link (1,15). Means (11,12) are provided for connecting the circuit element (14) to the resistive link (1,15). A laser-cut path extends entirely through the resistive link (1,15) in a direction that is at an angle in the range of approximately 0 to 60 degrees with respect to a longitudinal axis of the resistive link (1,15). Previously melted and re-solidified resistive link debris pieces (20A) remaining in the trim region are spaced sufficiently far apart and sufficiently far from a stub (15A) of the resistive link (15) to prevent significant leakage current from flowing through the resistive link (15).

### BRIEF DESCRIPTION OF THE DRAWINGS

FIGS. 1A-1D show plan views of a prior art technique, illustrating successive stages of lateral movement of a laser beam from left to right across a resistive link to perform laser cutting through the resistive link.

FIGS. 2A-2D show a sequence of plan views illustrating an offset path, from right to left of, the laser beam shown in FIGS. 1A-1D through the previously laser-cut region of the resistive link to remove residual resistive debris from the trim region.

FIG. 3 is a plan view diagram of laser-cut resistive links illustrating resistive debris remaining therein after a lateral laser cut made in accordance with the prior art technique shown in FIGS. 1A-1D

FIG. 4 is a section view diagram along section lines 4-4 of FIG. 3.

FIGS. 5A-5C show longitudinal laser cutting of a resistive link in accordance with the present invention.

FIGS. 6A-6D show diagonal laser trimming of a resistive link in accordance with the present invention.

FIG. 7 is a plan view diagram of laser-cut resistive links illustrating resistive debris remaining therein after a 25° diagonal laser cut made in accordance with the present invention.

FIG. 8 is a section view, taken along section lines 8-8 in FIG. 7.

FIG. 9 is a plan view illustrating resistive debris left after multiple diagonal laser cuts through a resistive link.

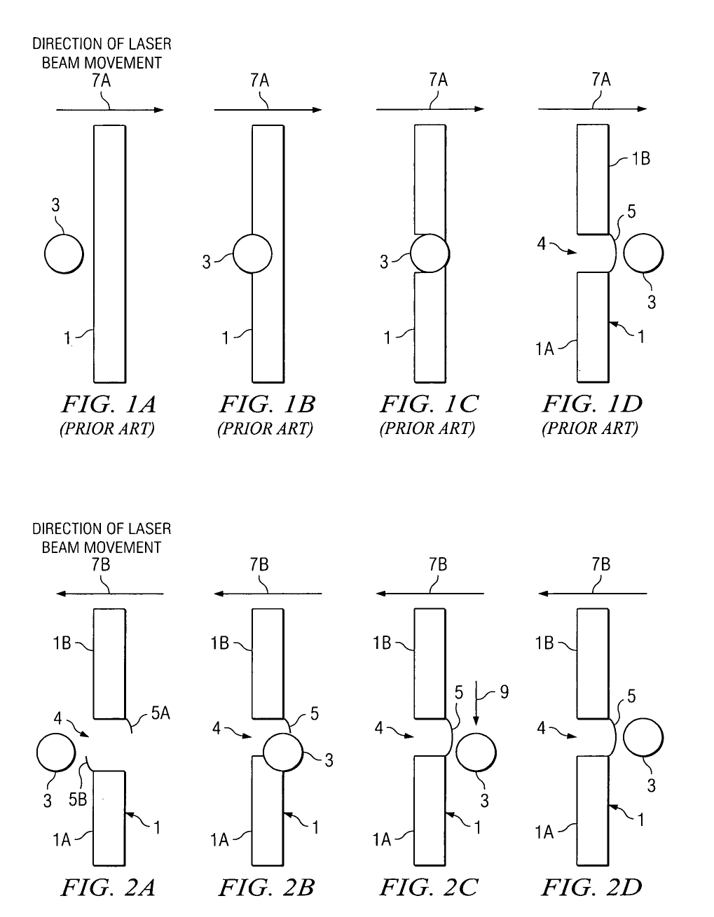

### DETAILED DESCRIPTION OF THE PREFERRED EMBODIMENTS

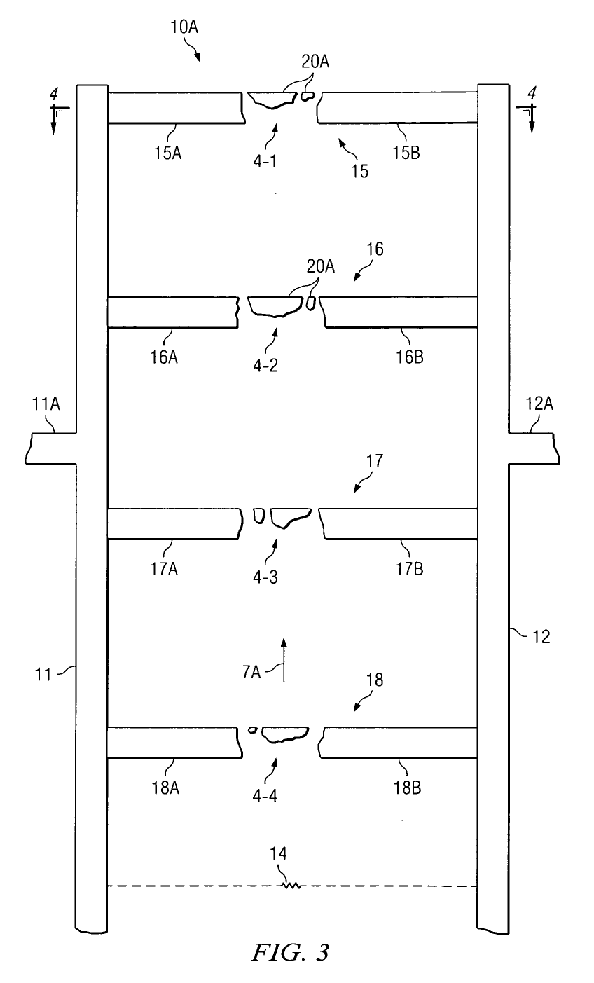

FIG. 3 shows a line drawing representation of a photograph taken in the course of evaluating the results of the previously described lateral laser cutting of SiCr links in a thin film resistor structure 10A on an integrated circuit chip. Resistive link test structure 10A includes four trimmable SiCr resistive links 15-18 connected in parallel between aluminum metallization traces 11 and 12. In an integrated circuit, a resistor 14, indicated in dashed lines, would be connected between metallization traces 11 and 12, and sections 11A and 12A of aluminum traces 11 and 12, respectively, would connect the resistor and trimmable resistive link structure 10A to other circuitry (not shown) on the same integrated circuit chip. (The interconnect conductors 11 and 12 in FIG. 3 could be composed of metals other than aluminum, or they could be composed of doped polycrystalline silicon connected by suitable vias to the resistive links.) Resistor 14 can be composed of the same material as the resistive links 15-18 or different material. Although the above described resistive links are composed of SiCr, they can be composed of various other materials, such as NiCr, NiCr alloy, SiCr alloys, various NiCr or SiCr silicides, TiN, TiN alloys, TaN, Ta alloys, polycrystalline silicon, or cermet material, or the like.

Typically, each SiCr link can be as narrow as the minimum process geometry dimension for the particular integrated circuit manufacturing process being utilized. For example, 1.4 microns can be the minimum process geometry dimension, although for a different process the minimum process geometry dimension might be 0.3 microns. Each SiCr link may be as wide as 25 microns or more, depending on the design rules of the integrated circuit manufacturing process being used. A typical thickness of the SiCr links may be approximately 35 Angstroms, although the thickness is dependent on the desired sheet resistance of the SiCr material, which might be much thicker, e.g., 380 Angstroms. The number of resistive links utilized in a trimmable resistor of an integrated circuit in which laser trimming of resistive links is to be performed may depend on the amount of resolution required in the integrated circuit. Typically, the diameter of a focused laser beam used for trimming resistive links may be approximately 7.5 microns, depending on the laser wavelength or various settings. Trim regions 4-1, 4-2, 4-3, and 4-4 in SiCr links 15-18 shown in FIG. 3 have therein various chromium debris pieces 20A which are produced as a result of the prior art lateral laser cutting procedure. The debris pieces 20A usually do not extend beyond the channels formed by the oxide layer that surrounds the SiCr links.

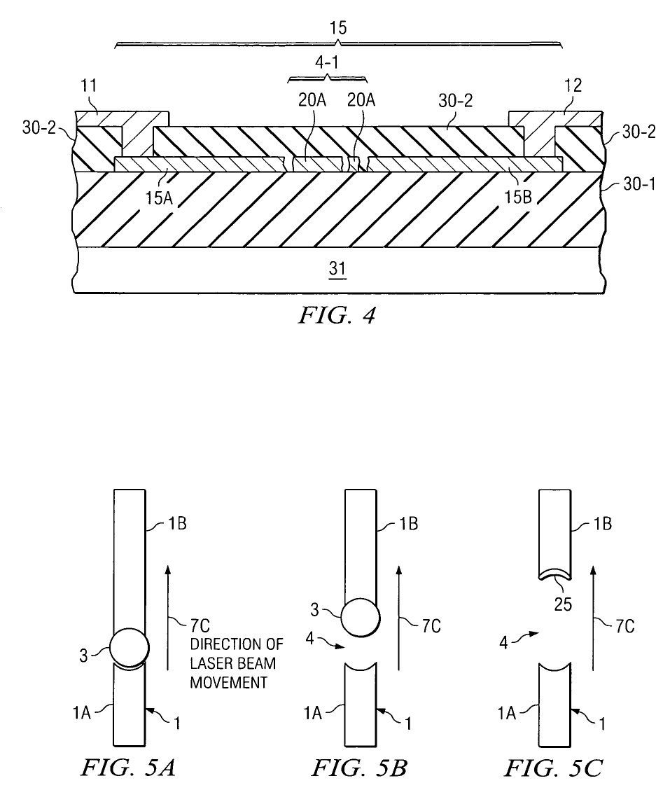

The section view of FIG. 4, along section lines 4-4 of FIG. 3, shows various chromium debris pieces 20A in trim region 4-1. The thickness of the debris pieces 20A typically is approximately equal to the thickness of the SiCr links 15-18. FIG. 4 shows a typical SiO₂ “stack” 30-1 formed on a silicon substrate 31. SiCr link 15 is formed and appropriately patterned on the upper surface of SiO₂ stack 30-1 of various SiO₂ sublayers (not shown). SiO₂ layer 30-2 then is formed to cover both SiCr link 15 and the top surface of SiO₂ stack 30-1. Aluminum interconnect conductors 11 and 12 are formed and appropriately patterned on SiO₂ layer 30-2 and make electrical contact to the opposite end portions, respectively, of SiCr link 15 through appropriate contact openings in SiO₂ layer 30-2. FIG. 4 also shows the SiCr stub sections 15A and 15B of SiCr link 15 which bound the cut out trim region 4-1 after the mid-portion of SiCr link 15 has been melted by, and to an extent, swept away by, the lateral movement of laser beam 3.

A test procedure was performed on a substantial number of SiCr links of the kind illustrated in FIG. 3 after they were subjected to a lateral laser-cutting operation as described above, leaving the various chromium debris pieces 20A in their associated trim regions 4-1,2,3,4. The test procedure included applying a 200 volt ramp voltage across each SiCr link.

The above described testing resulted in roughly 30% of the laterally laser-trimmed SiCr links failing the test, either (1) because a voltage-dependent leakage current significantly greater than approximately 10⁻¹¹ amperes flowed through the laterally laser-cut SiCr link between stubs 1A and 1B at relatively low values of the applied ramp voltage, or (2) because the SiCr link being tested experienced a voltage breakdown after which a leakage current substantially greater than approximately 10⁻¹¹ amperes flowed between the SiCr stubs 1A and 1B of that SiCr link. That is, a SiCr link was considered to be “reliable” only if a 200 volt ramp voltage could be applied across the SiCr link without causing any leakage current either significantly greater or significantly less than the initial leakage current, i.e., significantly greater or less than approximately 10⁻¹¹ amperes, to flow through the link at any applied voltage up to 200 volts.

Evaluation of the results of lateral laser cutting of SiCr links as shown in FIGS. 3 and 4 indicates that a basic problem of the prior art technique of lateral laser cutting is that part of the SiCr material melted by laterally advancing laser beam 3 tends to be “pushed” against the SiO₂ 30-2 surrounding trimmed link 15 but has no place to flow except back into trim region 4-1 as laser beam 3 advances laterally across trim region 4-1. That melted chromium material then solidifies in trim region 4-1 to form the various chromium debris pieces 20A when laser beam 3 either is turned off or has moved beyond SiCr link 1. It is believed that the various chromium debris pieces 20A are sufficiently close together to provide current leakage paths that result in a large likelihood of “failure” of the SiCr links.

To avoid the above described resistive link failures due to the prior art technique of lateral laser trimming of resistive links, the present invention provides an improved method of laser-cutting SiCr links which avoids the above mentioned SiCr link failures. Referring to FIGS. 5A-5C, in one embodiment of the invention a laser beam 3 is moved longitudinally along the longitudinal axis of an intermediate trim region 4 of SiCr link 1, as indicated by arrow 7C. Three stages are shown in FIGS. 5A-5C to indicate the progression of laser beam spot 3 during the laser-cutting of SiCr link 1. In FIG. 5A, laser beam spot 3, the diameter of which is theoretically about 7.5 microns, is sufficiently large to allow laser beam 3 to melt all of the SiCr link material in its path as it advances through trim region 4, if SiCr link 1 is approximately 5 microns wide. In FIG. 5B, laser beam 3 has advanced part way through trim region 4 toward SiCr stub 1B, clearing most or all of the melted chromium material out of that portion of trim region 4. In FIG. 5C, laser beam 3 has completed its longitudinal cut through trim region 4 and has been turned off or moved to one side of link 1.

A melted SiCr “wavefront” 25 including most of the chromium material melted by laser beam 3 is “pushed” or “swept” by laser beam 3 against or “into” stub 1B as laser beam 3 advances and continues to melt stub 1B. However, some of the melted chromium material of the wavefront 25 may flow back into trim region 4 as laser beam 3 advances beyond it. It is believed that the melted chromium material then solidifies into chromium debris in trim region 4 when laser beam 3 is turned off (or moved aside). The final length of the gap between the inner edges of stubs 1A and 1B should be at least about 7 microns.

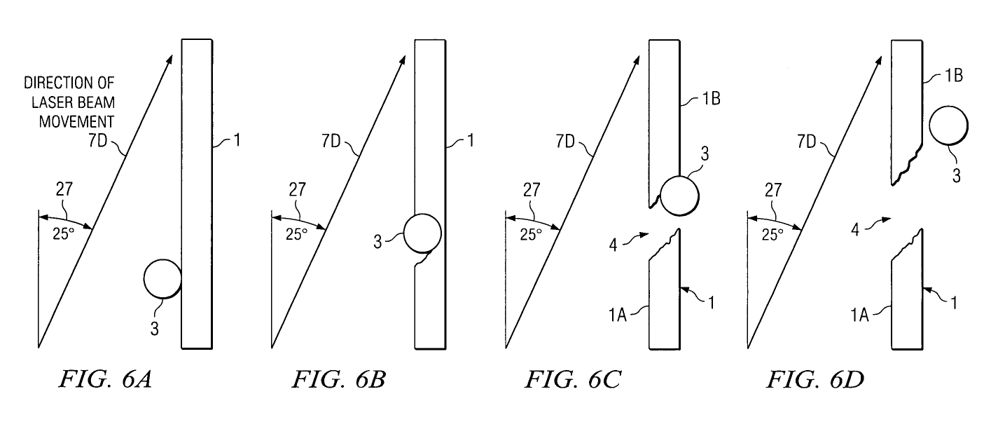

FIGS. 6A-6D show laser beam 3 advancing diagonally through laser-cutting SiCr link 1 at a 25 degree angle relative to the longitudinal axis of SiCr link 1, as indicated by arrow 7D. In FIG. 6A, laser beam spot 3 is just about to move into SiCr link 1. In FIG. 6B, laser beam 3 has advanced part way through trim region 4 of SiCr link 1, at a 25 degree angle relative to the longitudinal axis of SiCr link 1. In FIG. 6C, laser beam 3 has advanced, at a 25 degree angle, most of the way through link 1, melting and pushing or sweeping most of the chromium material from the left portions of trim region 4. In FIG. 6D, laser beam 3 has passed beyond SiCr link 4, and at that point has made a substantially wider cut through SiCr link 1 than would have been made by lateral movement of laser beam 3 through SiCr link 1. The average distance between the inner edges of SiCr stubs 1A and 1B when the laser cut is completed should be roughly 16 microns or more when used in conjunction with a secondary crosscut (not shown in FIG. 6D).

A typical wavelength of laser beam 3 might be approximately 1.3 microns, the laser spot size might be 7.5 microns, the laser pulse width might be 32 nanoseconds, the laser power range might be 0.14 to 1.4 micro-joules, and the laser step size might be in the range from approximately 0.1 to 3.75 microns, although the presently preferred range is about 0.5 to 1.0 microns. The laser pulse repetition frequency may be between about 500 to about 6000 pulses per second.

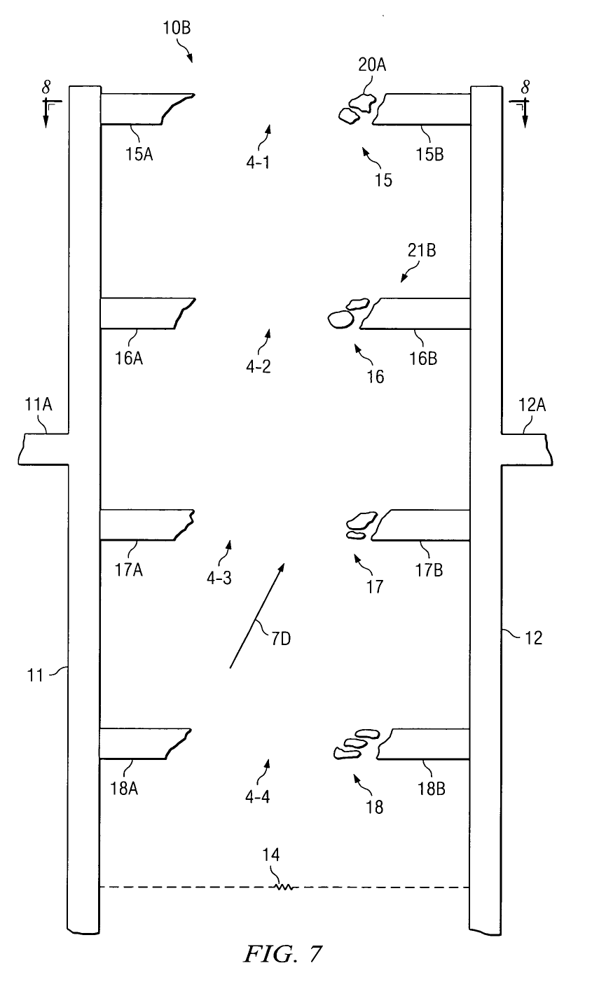

FIG. 7 shows a line drawing representation of a photograph taken in the course of evaluating the results of performing the foregoing 25 degree diagonal laser cross-cutting of SiCr links 15-18 in resistor structure 10B, which can be the same as thin film resistor structure 10A in FIG. 3. Each of SiCr links 15-18 in FIG. 7 can be 1.4 to 25 microns wide. Various chromium debris pieces 20A generated by the diagonal lateral laser cutting may remain in trim regions 4-1, 4-2, 4-3, and 4-4 of SiCr links 15-18, respectively. However, the width of an adequately “cleared out” portion of trim regions 4-1,2,3,4 is approximately 8 microns or more, which is substantially wider than would be the case for prior art lateral laser cuts made by the same laser beam 3, wherein the region cleared of chromium debris is much less than 8 microns wide. Also, there generally is a much greater distance separating the various chromium debris pieces in the cleared out portion of trim regions 4-1,2,3,4 from one remaining SiCr stub (15A, 16A, 17A, 18A) and the other stub (15B, 16B, 17B, 18B) than is the case in the previous lateral laser cut example FIGS. 3-5.

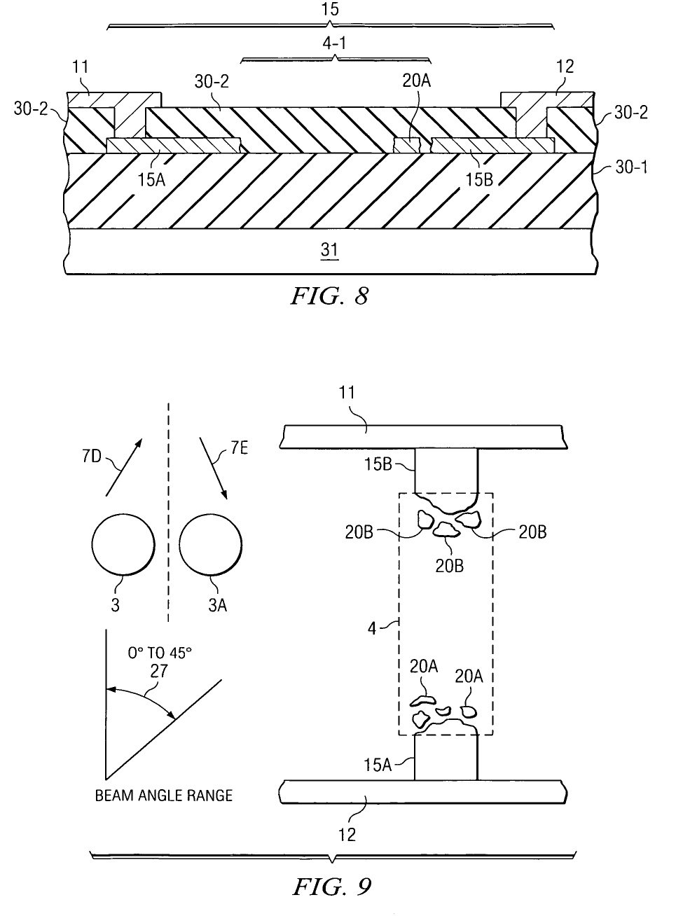

The section view in FIG. 8 along section lines 8-8 of FIG. 7 shows several chromium debris pieces in trim region 4-1. As in FIG. 3, FIG. 8 also shows SiO₂ stack 30-1 formed on a silicon substrate 31. SiCr link 15 is formed and appropriately patterned on the upper surface of SiO₂ “stack” 30-1 of various SiO₂ sublayers (not shown). SiO₂ layer 30-2 then is formed to cover SiCr link 15 and the upper surface of SiO₂ stack 30-1. Aluminum interconnect conductors 11 and 12 are formed and appropriately patterned on SiO₂ layer 30-2 and electrically contact the opposite end portions, respectively, of SiCr link 15 through appropriate openings in SiO₂ layer 30-2. FIG. 9 also shows the SiCr stub sections 15A and 15B of SiCr link 15 which bound trim region 4-1 after the mid-portion of SiCr link 15 has been melted and mostly swept away by the 25 degree diagonal movement of laser beam 3. (Note that as a practical matter, the angle of movement of laser beam 3 across SiCr links 15-18 in FIG. 7, relative to the longitudinal axis of the SiCr links, can be anywhere between 0 and 45 degrees. In some cases in which a very wide resistive link is to be laser-cut, the angle of movement of the laser beam may be greater than 45 degrees, perhaps as much as approximately 60 degrees.

The chromium debris melted by laser beam 3 are believed to have been quite effectively pushed or swept ahead of the advancing laser beam 3 as it advances in a selected advantageous direction. This is believed to result in leading edge filament orientations that do not result in short-circuiting across the remaining SiCr stubs in trim region 4-1. The chromium debris pieces left near the SiCr stubs are farther apart than is the case for the prior art lateral laser cuts, and are pushed back into SiCr stub 1A. Furthermore, the chromium debris pieces that do remain in trim region 4-1 tend to be located much closer to the 4A edge of SiCr stub 1B in FIGS. 6A-6D then would be the case for a lateral laser cut. It should be appreciated that the portion of trim region 4-1 closer to SiCr stub 1A of either a longitudinal laser cut or a diagonal laser cut is not a “critical” area in the sense that chromium debris pieces are likely to remain there and cause failure of the SiCr link. The above described 25 degree diagonal laser cutting resulted in very high resistance and very low leakage current of the SiCr links compared to the result when prior lateral laser cutting techniques are used. The very low leakage currents and high resistance of the SiCr links shown in FIG. 7 is in direct contrast to the high leakage currents that occur in the laterally cut SiCr links shown in FIG. 3, in which closely-spaced chromium debris pieces relative to two remaining SiCr stubs are likely to be located throughout the trim region and are very likely to cause failure of the laser-cut link. Furthermore, since the length of the trim region melted by laser beam 3 is substantially longer than is the case for a prior art lateral laser cut, the maximum electric field intensity at any debris piece 20A would tend to be lower and therefore less likely to undergo electrical breakdown and an accompanying increase in leakage current through the laser-cut resistive link.

Thus, wide, relatively clean trim regions 4-1,2,3,4 in FIG. 7 are created by cutting SiCr links longitudinally or diagonally in accordance with the present invention. The diagonal cuts can be made at a sufficiently large angle relative to the longitudinal axes of the SiCr links to ensure that links as wide as, or even wider than, roughly 10 to 25 microns are fully cut without leaving enough chromium debris in the trim regions to cause measurable leakage currents through, or breakdown voltages across, the diagonally laser-cut SiCr links. The longitudinal or diagonal laser trimming procedure of the present invention has been found to result in very reliable laser-cut SiCr links having very low leakage currents, of the order of 10⁻¹¹ amperes in response to a 200 volt test signal applied across the laser-cut SiCr links.

Referring to FIG. 9, a resistive link has been diagonally laser-cut twice, first by laser beam spot 3 advancing in a first direction indicated by arrow 7D, and again by laser beam spot 3A advancing in a second direction indicated by arrow 7E. This has resulted in the trim region indicated by dashed line 4 in which the inner ends of resistive link stubs 15A and 15B are somewhat rounded, rather than inclined as indicated in FIG. 6D wherein only a single inclined cut has been made by laser beam spot 3. The second cut in direction 7E “rounds off” the right inner edge portion of stub 15A and the inner left edge portion of stub 15B. A few resistive debris pieces 20B are produced in trim region 4 by the first laser beam spot 3 near the inner edge of stub 15B at the end of the first laser beam pass, and a few resistive debris pieces 20A are produced in trim region 4 at the end of the path of second laser beam spot 3A, near the inner edge of stub 15A at the end of the second laser beam pass. The distance between debris pieces 20A and debris pieces 20B is sufficiently large, for example, greater than roughly 15 microns, to prevent leakage current paths from occurring and to prevent electrical breakdown from occurring during the above described 200 volt ramp testing procedure. (It should be appreciated that the second direction 7E can be either symmetrical or asymmetrical with respect to the first direction 7D.)

It also has been found that longitudinal or diagonal laser cuts in accordance with the present invention avoid or mitigate the formation of the above mentioned trailing edge filaments 5 and also reduce the amount of chromium debris in the trim regions between the opposite link stubs of each laser-cut SiCr link. Compared to laterally laser-cut SiCr links, the trim regions of the longitudinally or diagonally laser-cut SiCr links of the present invention are well cleared of any re-flown and re-solidified chromium residue.

Thus, the longitudinal or diagonal laser-cutting method of the present invention quite effectively pushes or sweeps laser-melted chromium residual material out of the trim regions of the SiCr links ahead of the laser beam path and effectively widens the longitudinal or diagonal laser cut enough that there is essentially no change in initial leakage current when the diagonally or longitudinally trimmed link is subjected to a 200 volt ramp voltage. Furthermore, there is no electrical breakdown in the laser-cut trim region when the diagonally or longitudinally trimmed link is subjected to a 200 volt ramp voltage, and the leakage current is no more than approximately 10⁻¹¹ amperes. In some cases, the longitudinal or diagonal cuts also mitigate laser-positioning errors.

While the invention has been described with reference to several particular embodiments thereof, those skilled in the art will be able to make various modifications to the described embodiments of the invention without departing from its true spirit and scope. It is intended that all elements or steps which are insubstantially different from those recited in the claims but perform substantially the same functions, respectively, in substantially the same way to achieve the same result as what is claimed are within the scope of the invention.

What is claimed is:

1. A method of adjusting a resistance of a resistive structure including a first resistor and a first resistive link, the method comprising:
(a) providing the first resistor and the first resistive link in a structure being fabricated;
(b) forming a dielectric layer over the first resistive link;
(c) connecting the first resistor and the first resistive link in parallel; and
(d) forming a cut entirely through the first resistive link by advancing a laser beam through a trim region of the first resistive link in a direction that is at an angle in the range of approximately 0 to 60 degrees with respect to a longitudinal axis of the first resistive link so as to melt material of the first resistive link in the trim region.

2. The method of claim 1 wherein step (a) includes forming a plurality of resistive links in an integrated circuit structure, step (b) includes forming the dielectric layer over the plurality of resistive links, step © includes connecting the first resistor and the plurality of resistive links in parallel, and step (d) includes forming cuts entirely through each of the plurality of resistive links, respectively, respectively, by advancing the laser beam through trim regions of the plurality of resistive links in directions that are at angles in the range of 0 to 45 degrees with respect to longitudinal axes of the plurality of resistive links, respectively, so as to melt resistive material of the plurality of resistive links in the trim regions thereof.

3. The method of claim 1 wherein the first resistive link is approximately 5 microns wide.

4. The method of claim 3 wherein the diameter of the laser beam where it impinges on the first resistive link is approximately 7.5 microns.

5. The method of claim 1 wherein the first resistive link is approximately 35 angstroms thick.

6. The method of claim 1 wherein the angle is 25 degrees.

7. The method of claim 1 wherein the angle is zero degrees.

8. The method of claim 1 wherein step (b) includes forming the dielectric layer of SiO₂.

9. The method of claim 1 wherein step (d) includes melting material of the first resistive link by advancing the laser beam in the vicinity of the cut and thereby sweeping melted material of the first resistive link in the direction in which the laser beam is advancing.

10. The method of claim 9 wherein the sweeping results in re-solidified debris pieces remaining in the vicinity of the cut and being located sufficiently far from an edge of the cut to prevent leakage current from flowing through the first resistive link after it has been laser-cut.

11. The method of claim 2 wherein the plurality of resistive links includes four resistive links.

12. The method of claim 1 wherein the first resistive link is composed of a material from the group consisting of NiCr, NiCr alloy, SiCr alloy, NiCr silicide, SiCr silicide, TiN, TiN alloy, TaN, Ta alloy, polycrystalline silicon, and cermet material.

13. The method of claim 2 wherein step © includes connecting the first resistor and the plurality of resistive links in parallel by connecting a first interconnect metallization trace to a first terminal of each of the first resistor and the plurality of resistive links and connecting a second interconnect metallization trace to a second terminal of each of the first resistor and the plurality of resistive links.

14. The method of claim 1 including forming the first resistor and the first resistive link of the same kind of material.

15. The method of claim 7 including, after step (d), advancing the laser beam through the trim region in a direction opposite to the direction recited in step (d).

16. The method of claim 1 including, after step (d), advancing the laser beam through the trim region in a direction other than the direction recited in step (d) so as to round off edges of first and second stubs of the first resistive link.

17. An integrated circuit structure comprising:
(a) a circuit element and a resistive link;
(b) a dielectric layer disposed on the resistive link;
(c) a conductor for connecting the circuit element to the resistive link; and
(d) a laser-cut path extending entirely through the resistive link in a direction that is at an angle in the range of approximately 0 to 60 degrees with respect to a longitudinal axis of the resistive link.

18. The resistor structure of claim 17 wherein the connecting means includes a first interconnect metallization trace on the dielectric layer connected to a first terminal of each of the circuit element and the resistive link and a second interconnect metallization trace connected to a second terminal of each of the circuit element and the resistive link to thereby connect the resistive link in parallel with the circuit element.

19. The resistor structure of claim 17 including previously melted and re-solidified resistive link debris pieces spaced sufficiently far apart and sufficiently far from a stub of the resistive link to prevent significant leakage current from flowing through the resistive link.

20. A resistive structure including a resistor and a resistive link and made by the process of:
(a) providing the resistor and the first link in an integrated circuit structure being fabricated;
(b) forming a dielectric layer the resistive link;
(c) connecting the resistor and the resistive link in parallel; and
(d) forming a cut entirely through the resistive link by advancing a laser beam through a trim region of the resistive link in a direction that is at an angle in the range of approximately 0 to 60 degrees with respect to a longitudinal axis of the resistive link so as to melt material of the resistive link in the trim region.
